(19) United States
(12) Patent Application Publication
(10) Pub. No.: US 2018/0294431 A1
(43) Pub. Date: Oct. 11, 2018

(54) ORGANIC EL DISPLAY DEVICE

(71) Applicant: Japan Display Inc., Minato-ku (JP)

(72) Inventors: Hironori TOYODA, Minato-ku (JP); Takahiro USHIKUBO, Minato-ku (JP)

(73) Assignee: Japan Display Inc., Minato-ku (JP)

(21) Appl. No.: 15/920,598

(22) Filed: Mar. 14, 2018

(30) Foreign Application Priority Data
Apr. 6, 2017 (JP) 2017-075934

(51) Int. Cl. H01L 51/52; H01L 51/50

(52) U.S. Cl. CPC H01L 51/5234; H01L 51/5004; H01L 51/5092; H01L 51/5072; H01L 51/5278; H01L 2251/306; H01L 2251/308; H01L 2251/558; H01L 51/5044

(57) ABSTRACT

An organic EL display device includes an anode, an organic light-emitting unit formed on the anode, and a cathode formed on the organic light-emitting unit and containing In. The organic light-emitting unit includes a light-emitting layer, and an electron injection layer formed between the cathode and the light-emitting layer, and an In concentration in layers of the organic light-emitting unit other than the electron injection layer is equal to or less than one-twentieth that in the cathode.

### CROSS-REFERENCE TO RELATED APPLICATION

The present application claims priority from Japanese Application JP2017-75934 filed on Apr. 6, 2017, the content of which is hereby incorporated by reference into this application.

### BACKGROUND OF THE INVENTION

### 1. Field of the Invention

The present invention relates to an organic EL display device.

### 2. Description of the Related Art

In an organic EL display device of a top emission type, a transparent conductive film made of indium zinc oxide (IZO) or the like is formed as a cathode on a light-emitting unit including a light-emitting layer (see JP 2009-295822 A). Such a transparent conductive film is generally formed by a sputtering method.

In the light-emitting unit on which the transparent conductive film is formed, the resistivity becomes high or the lifetime of the light-emitting layer is shortened in some cases. The inventors of the present application have found that the cause of the high resistivity or the shortening of the lifetime is the diffusion of the material of the transparent conductive film into the light-emitting unit during the formation of the transparent conductive film.

### SUMMARY OF THE INVENTION

The invention has been made in view of the above problems, and it is an object of the invention to provide an organic EL display device capable of achieving the lower resistance of a light-emitting unit and the longer lifetime of a light-emitting layer.

According to one aspect of the present invention, there is provided an organic EL display device including an anode, an organic light-emitting unit formed on the anode, and a cathode formed on the organic light-emitting unit and containing In. The organic light-emitting unit includes a light-emitting layer, and an electron injection layer formed between the cathode and the light-emitting layer, and an In concentration in layers of the organic light-emitting unit other than the electron injection layer is equal to or less than one-twentieth that in the cathode.

In the above-mentioned aspects of the invention, an In concentration in the light-emitting layer is equal to or less than one-twentieth that in the cathode.

In the above-mentioned aspects of the invention, the organic light-emitting unit further includes an electron transport layer formed between the electron injection layer and the light-emitting layer, and an In concentration in the electron transport layer is equal to or less than one-twentieth that in the cathode.

In the above-mentioned aspects of the invention, the organic EL display device further includes a cathode buffer layer formed between the cathode and the organic light-emitting unit and containing an alkali metal or an alkaline earth metal as a main component.

In the above-mentioned aspects of the invention, the cathode buffer layer contains Ca as a main component.

In the above-mentioned aspects of the invention, an In concentration in the electron injection layer is also equal to or less than one-twentieth that in the cathode.

In the above-mentioned aspects of the invention, the electron injection layer is doped with an alkali metal, and the thickness of the electron injection layer is equal to or greater than two times that of the electron transport layer.

According to another aspect of the present invention, there is provided an organic EL display device including an anode, an organic light-emitting unit formed on the anode, a cathode formed on the organic light-emitting unit and containing In, and a cathode buffer layer formed between the cathode and the organic light-emitting unit and containing an alkali metal or an alkaline earth metal as a main component.

### BRIEF DESCRIPTION OF THE DRAWINGS

FIG. 1 is a diagram schematically showing a cross-sectional structure example of an organic EL display device.

FIG. 2 is a diagram schematically showing a stacked structure example of an organic film.

FIG. 3A is a diagram schematically showing a stacked structure example of a first embodiment.

FIG. 3B is a diagram showing analysis results of an In concentration in the first embodiment.

FIG. 4A is a diagram schematically showing a stacked structure example of a second embodiment.

FIG. 4B is a diagram showing analysis results of an In concentration in the second embodiment.

FIG. 5 is a diagram showing analysis results of an In concentration in a reference example.

FIG. 6 is a graph representing an initial voltage of a light-emitting unit by a relative value.

FIG. 7A is a graph representing the emission lifetime of the light-emitting unit by a relative value.

FIG. 7B is a graph representing the relationship between the In concentration and the emission lifetime.

FIG. 8A is a graph representing an energizing voltage rise of the light-emitting unit by a relative value.

FIG. 8B is a graph representing the relationship between the In concentration and the energizing voltage rise.

### DETAILED DESCRIPTION OF THE INVENTION

Hereinafter, each embodiment of the invention will be described with reference to the drawings. The disclosure is illustrative only. Appropriate modifications that will readily occur to those skilled in the art and fall within the spirit of the invention are of course included in the scope of the invention. In the drawings, the width, thickness, shape, and the like of each part may be schematically represented, compared to those in embodiments, for more clarity of description. However, they are illustrative only, and do not limit the interpretation of the invention. Moreover, in the specification and the drawings, elements similar to those described in relation to a previous drawing are denoted by the same reference numerals and signs, and a detailed description may be appropriately omitted.

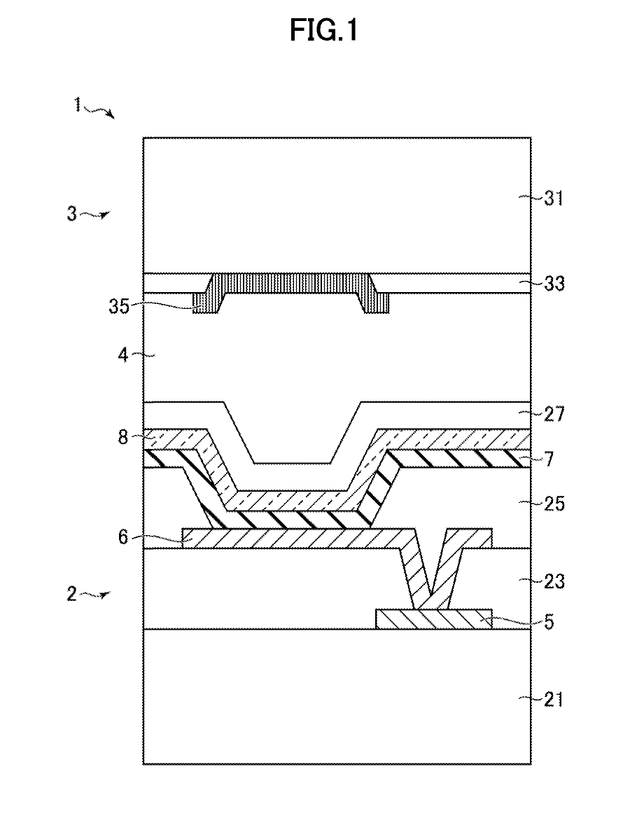

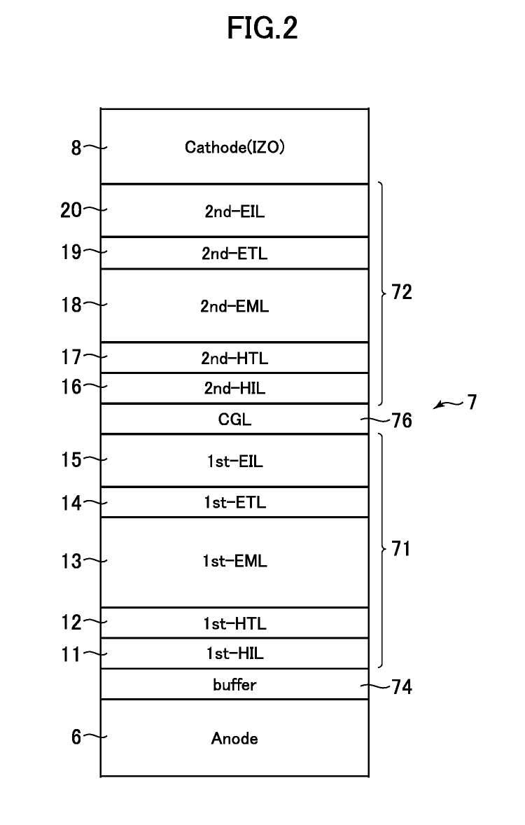

FIG. 1 is a diagram schematically showing a cross-sectional structure example of an organic EL display device 1 according to an embodiment of the invention. In FIG. 1, insulating films 23 and 25 and the like are not hatched in order to facilitate viewing of the cross-sectional structure. FIG. 2 is a diagram schematically showing a stacked structure example of an organic film 7 (organic EL element) included in the organic EL display device 1.

The organic EL display device 1 includes an array substrate 2 and a counter substrate 3 opposed to the array substrate 2. The array substrate 2 and the counter substrate 3 are bonded together with a filling material 4 therebetween. In the organic EL display device 1, a top emission type in which light is emitted in the direction of the counter substrate 3 with respect to the array substrate 2 is employed. In the following description, the direction of the counter substrate 3 with respect to the array substrate 2 is defined as an upper direction.

The array substrate 2 is a stacked body in which an insulating film and a conductor layer are stacked on a transparent substrate 21 made of, for example, glass or resin having flexibility such as polyimide. A lower-layer electrode 5 is an electrode that is connected to a TFT (not shown) for driving, for example, a pixel. The lower-layer electrode 5 is formed of a conductive metal such as, for example, aluminum, silver, copper, nickel, or titanium.

The lower-layer electrode 5 is covered by the insulating film 23. An anode 6 corresponding to each pixel is disposed on the insulating film 23. An opening for connecting the anode 6 to the lower-layer electrode 5 is formed in the insulating film 23. The insulating film 23 is formed of an organic insulating material such as, for example, acrylic resin, and the surface thereof is flattened. The anode 6 is formed of a conductive metal such as, for example, aluminum, silver, copper, nickel, or titanium, and includes a reflective surface.

The insulating film 23 and the anode 6 are covered by the insulating film 25. An opening where the anode 6 is exposed at the bottom is formed in the insulating film 25. The insulating film 25 is also called a pixel separation film, a bank, or a rib. The insulating film 25 is formed of a transparent organic material such as, for example, acrylic resin. The anode 6 exposed at the bottom of the opening of the insulating film 25 is covered by the organic film 7 including light-emitting layers. The details of the organic film 7 will be described later.

The organic film 7 is covered by a cathode 8. The cathode 8 is a transparent conductive film formed of a transparent conductive material such as, for example, indium zinc oxide (IZO) or indium tin oxide (ITO). The cathode 8 is covered by a sealing film 27. The sealing film 27 is formed of an inorganic insulating material such as, for example, silicon oxide or silicon nitride.

In the counter substrate 3, a black matrix 33 in which an opening corresponding to each pixel is formed, and a color filter 35 filled in the opening, are provided on a transparent substrate 31 made of, for example, glass or resin having flexibility such as polyimide. The counter substrate 3 may not be provided.

As shown in FIG. 2, the organic film 7 includes a first light-emitting unit 71 and a second light-emitting unit 72. The first light-emitting unit 71 is disposed on the side close to the anode 6, and the second light-emitting unit 72 is disposed on the side close to the cathode 8. A buffer layer 74 is disposed between the anode 6 and the first light-emitting unit 71. A separation layer 76 is disposed between the first light-emitting unit 71 and the second light-emitting unit 72.

The first light-emitting unit 71 includes, in order from the side close to the anode 6, a first hole injection layer (1st-HIL), a first hole transport layer 12 (1st-HTL), a first light-emitting layer 13 (1st-EML), a first electron transport layer 14 (1st-ETL), and a first electron injection layer 15 (1st-EIL).

The second light-emitting unit 72 includes, in order from the side close to the anode 6, a second hole injection layer 16 (2nd-HIL), a second hole transport layer 17 (2nd-HTL), a second light-emitting layer 18 (2nd-EML), a second electron transport layer 19 (2nd-ETL), and a second electron injection layer 20 (2nd-EIL).

Although two light-emitting units 71 and 72 are provided in the organic film 7 in the embodiment, one light-emitting unit may suffice. Moreover, the embodiment is configured such that, for example, the emission color of the first light-emitting layer 13 is yellow, the emission color of the second light-emitting layer 18 is blue, and thus white light is emitted as a whole; however, the emission color is not limited to them. For example, the light-emitting layer may emit red, green, or blue light.

As the material of the first light-emitting layer 13 and the second light-emitting layer 18, for example, various light-emitting materials including a fluorescent light-emitting material such as Alq3 (tris(8-quinolinolato)aluminum), or a phosphorescent light-emitting material such as “tris(2-phenylpyridinato-N,C2′)iridium(III)” (Ir(ppy)3), “tris(1-phenylisoquinoline)iridium(III)” (Ir(piq)3), or “bis[2-(4′,6′-difluorophenyl)pyridinato-N,C2′] iridium (III) picolinate” (FIrpic) can be used.

As the material of the first hole transport layer 12 and the second hole transport layer 17, for example, a material such as NPB (4,4′-bis[N-(1-naphthyl)-N-phenylamino]biphenyl) or TPD (N,N′-bis(3-methylphenyl)-N,N′-diphenyl-[1,1′-biphenyl]-4,4′-diamine) can be used.

As the material of the first electron transport layer 14 and the second electron transport layer 19, for example, a material such as Alq3 or BCP (bathocuproine) can be used.

As the material of the first electron injection layer 15 and the second electron injection layer 20, for example, an electron injection material doped with an alkali metal can be used. As the electron injection material, for example, an organic material such as Alq3 (tris(8-quinolinolato)aluminum) or BCP (bathocuproine) can be used. Examples of the alkali metal include Li, Na, K, Rb, Cs, and Fr.

Each layer included in the organic film 7 is formed by a method such as, for example, a vacuum evaporation method, a coating method, or a printing method. Further, the cathode 8 made of a transparent conductive material such as indium zinc oxide (IZO) is formed on the second light-emitting unit 72 of the organic film 7, that is, on the second electron injection layer 20, by a sputtering method.

Hereinafter, more specific details of the embodiment will be described.

In general, when a transparent conductive film of IZO or the like is formed on the light-emitting unit by a sputtering method, the resistivity of the light-emitting unit tends to be high or the lifetime of the light-emitting layer tends to be shortened. The inventors of the present application have found that the cause of the higher resistivity or the lifetime reduction is the diffusion of indium (In), which is the material of the transparent conductive film, into the light-emitting unit when the transparent conductive film of IZO or the like is formed on the light-emitting unit by a sputtering method.

For example, when In is present in the light-emitting unit, carriers are trapped by In and thus a current is less likely to flow even when a voltage is applied. That is, the presence of In may be the cause of the higher resistivity. Moreover, when In is present in the light-emitting layer, carriers are trapped and, in addition, exciton energy may be quenched by In. That is, the presence of In may be the cause of the lifetime reduction.

Therefore, the inventors of the present application have achieved the suppression of the higher resistivity and the lifetime reduction due to the diffusion of indium (In) by first and second embodiments to be described below.

### First Embodiment

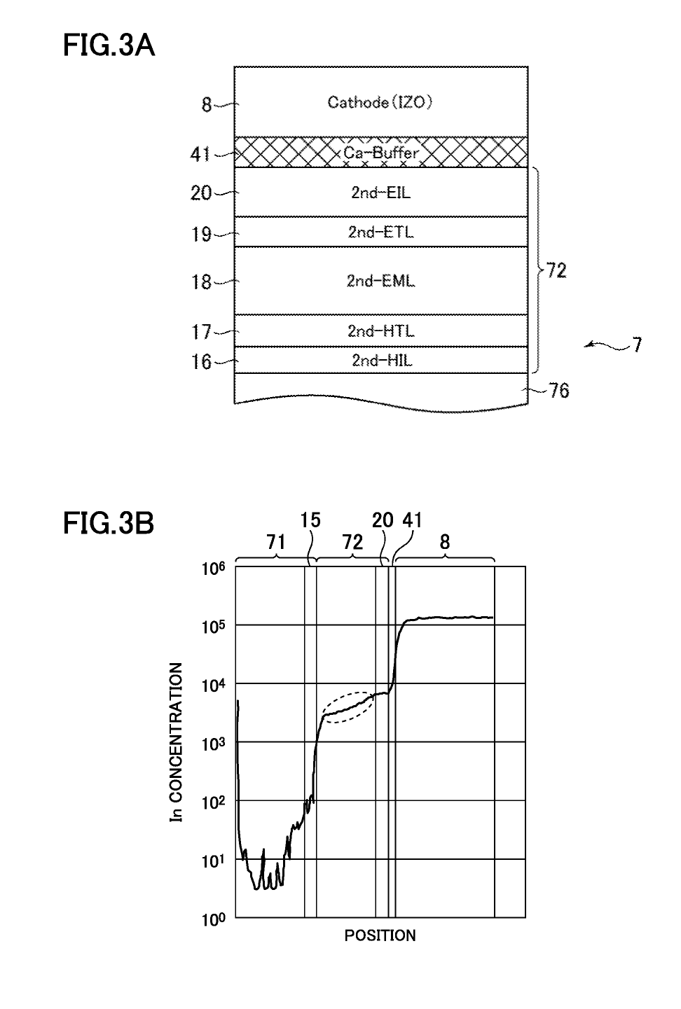

FIG. 3A is a diagram schematically showing a stacked structure example of the first embodiment. Configurations that are redundant with those of FIG. 2 are denoted by the same numbers, and will not be described in detail. FIG. 3B is a graph showing analysis results of an In concentration in the first embodiment (details will be described later).

In the first embodiment, a cathode buffer layer 41 is formed between the cathode 8 and the second light-emitting unit 72. The cathode buffer layer 41 contains an alkali metal or an alkaline earth metal as a main component. Examples of an alkali metal include, for example, Li, Na, and K. Examples of an alkaline earth metal include, for example, Be, Mg, and Ca. It is considered that these atoms function as a barrier to suppress the entry of indium (In) into the second light-emitting unit 72 and also function as an electron supply source.

Representatively, the cathode buffer layer 41 contains Ca as a main component. The cathode buffer layer 41 is, for example, a Ca crystal layer made of Ca crystals. The Ca crystal layer is formed on the second light-emitting unit 72 by, for example, a vacuum evaporation method or a sputtering method. The thickness of the Ca crystal layer is preferably, for example, approximately 1 nm or more and 10 nm or less. When the thickness is less than 1 nm, the Ca crystal layer is poor in stability as a film, such that the Ca crystal layer is formed in an island shape. When the thickness exceeds 10 nm, the luminous efficiency of the element may be lowered due to optical absorption.

### Second Embodiment

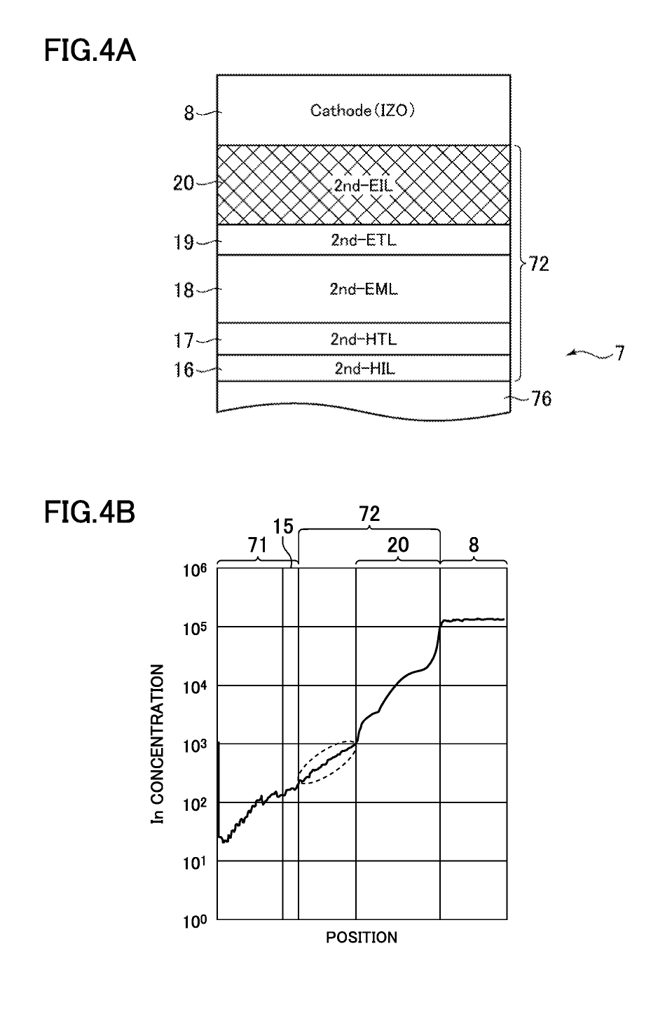

FIG. 4A is a diagram schematically showing a stacked structure example of the second embodiment. Configurations that are redundant with those of FIG. 2 are denoted by the same numbers, and will not be described in detail. FIG. 4B is a graph showing analysis results of an In concentration in the second embodiment (details will be described later).

As another means of suppressing damage to the light-emitting layer due to the diffusion of indium (In), the inventors of the present application have conceived of increasing the distance between the transparent conductive film and the light-emitting layer more than a conventional one.

When it is intended to increase the distance between the cathode 8 and the second light-emitting layer 18 in, for example, the stacked structure of FIG. 2, there are three conceivable ways: one is to thicken only the second electron transport layer 19; another is to thicken only the second electron injection layer 20; and the third is to thicken both the second electron transport layer 19 and the second electron injection layer 20.

However, the thickening of the layer leads to an increase in electrical resistance and thus leads to an increase in power consumption, thereby causing a problem in that it is desired to suppress an increase in electrical resistance as much as possible while increasing the distance between the cathode 8 and the second light-emitting layer 18 for suppressing the damage to the second light-emitting layer 18.

In the embodiment, therefore, the ratio of the thickness of the second electron injection layer 20 to the thickness of the second electron transport layer 19 is relatively increased. It has been found that the configuration described above provides an advantageous effect that an increase in electrical resistance can also be suppressed while suppressing the damage to the second light-emitting layer 18. It is considered that this is because the second electron injection layer 20 is doped with an alkali metal such as Li and the electrical resistance of the second electron injection layer 20 is smaller than that of the second electron transport layer 19.

Specifically, the thickness of the second electron injection layer 20 is preferably equal to or greater than two times, more preferably equal to or greater than 2.5 times, and still more preferably equal to or greater than three times that of the second electron transport layer 19. With the configuration described above, the above advantageous effect can be obtained. On the other hand, if the second electron injection layer 20 is too thick, the above advantageous effect is saturated; therefore, the thickness of the second electron injection layer 20 is preferably equal to or less than six times, and more preferably equal to or less than five times that of the second electron transport layer 19.

The thickness of the second electron injection layer 20 is preferably 35 nm or more, more preferably 45 nm or more, and still more preferably 55 nm or more. With the configuration described above, the above advantageous effect can be obtained. On the other hand, if the second electron injection layer 20 is too thick, the above advantageous effect is saturated; therefore, the thickness of the second electron injection layer 20 is preferably 120 nm or less, and more preferably 100 nm or less.

The thickness of the second electron transport layer 19 is preferably 20 nm or less, more preferably 15 nm or less, and still more preferably 10 nm or less. With the configuration described above, the above advantageous effect can be obtained. On the other hand, in order to fulfill the function of the second electron transport layer 19, the thickness of the second electron transport layer 19 is preferably 5 nm or more.

The thicknesses of the second electron transport layer 19, the second electron injection layer 20, and the cathode 8 are determined based on optical distances; therefore, when the thickness of the second electron injection layer 20 is intended to be increased, it is preferable to reduce the thickness of the cathode 8 in response to the thickness of the second electron injection layer 20. For this reason, the ratio of the thickness of the second electron injection layer 20 to the thickness of the cathode 8 is relatively increased in the embodiment.

Specifically, the thickness of the second electron injection layer 20 is preferably equal to or greater than one-eighth, more preferably equal to or greater than one-sixth, and still more preferably equal to or greater than one-fourth that of the cathode 8. With the configuration described above, it is possible to obtain the above advantageous effect while suppressing the total thickness of the second electron injection layer 20 and the cathode 8. On the other hand, if the second electron injection layer 20 is too thick, the above advantageous effect is saturated; therefore, the thickness of the second electron injection layer 20 is preferably equal to or less than one-half, and more preferably equal to or less than one-third that of the cathode 8.

The thickness of the cathode 8 is preferably 260 nm or less, more preferably 250 nm or less, and still more preferably 240 nm or less. With the configuration described above, the above advantageous effect can be obtained. Moreover, by making the cathode 8 relatively thin, it is possible to shorten the formation time of the cathode 8. On the other hand, in order to fulfill the function of the cathode 8, the thickness of the cathode 8 is preferably 180 nm or more, and more preferably 200 nm or more.

The first embodiment and the second embodiment have been individually described above; however, these embodiments may be combined together. That is, the cathode buffer layer 41 may be formed between the cathode 8 and the second light-emitting unit 72, and also, the thickness of the second electron injection layer 20 may be increased relative to the second electron transport layer 19.

Hereinafter, analysis results of an In concentration shown in FIGS. 3B, 4B, and 5 will be described. The analysis of the In concentration has been performed by time-of-flight secondary ion mass spectrometry (TOF-SIMS). In FIGS. 3B, 4B, and 5, the horizontal axis represents the position in a layer thickness direction, while the vertical axis represents the In concentration on a log scale.

In the first embodiment according to FIG. 3B, it is assumed that, for example, the thickness of the cathode 8 is 280 nm, the thickness of the cathode buffer layer 41 is 5 nm, the thickness of the second electron injection layer 20 is 20 nm, and the thickness of the second electron transport layer 19 is 20 nm.

In the second embodiment according to FIG. 4B, it is assumed that, for example, the thickness of the cathode 8 is 240 nm, the thickness of the second electron injection layer 20 is 60 nm, and the thickness of the second electron transport layer 19 is 20 nm. It is sufficient for the second electron injection layer 20 to have a thickness of at most 20 nm in order to fulfill the electron injection function thereof; however, in the second embodiment, the thickness of the second electron injection layer 20 is set to be greater than that.

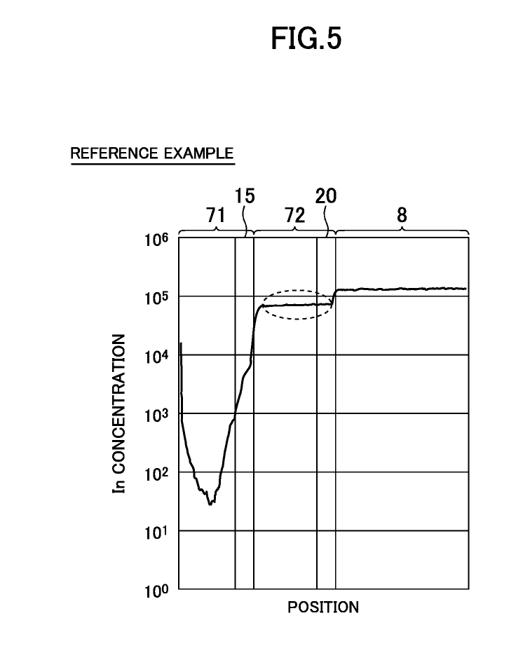

In a reference example according to FIG. 5, it is assumed that, for example, the thickness of the cathode 8 is 280 nm, the thickness of the second electron injection layer 20 is 20 nm, and the thickness of the second electron transport layer 19 is 20 nm. That is, in the reference example, the cathode buffer layer 41 as in the first embodiment is not provided, and also, the thick second electron injection layer 20 as in the second embodiment is not provided.

It is assumed that the thicknesses of the other layers are the same as each other. Moreover, it is assumed that the materials and formation conditions of the layers are the same as each other.

In the first and second embodiments shown in FIGS. 3B and 4B, the In concentration in the layers of the second light-emitting unit 72 other than the second electron injection layer 20 is equal to or less than one-twentieth that in the cathode 8 (the portion surrounded by the broken line in the graph). That is, the In concentration in the second electron transport layer 19 and the second light-emitting layer 18 is equal to or less than one-twentieth that in the cathode 8. In the first embodiment, the In concentration in the second electron injection layer 20 is also equal to or less than one-twentieth that in the cathode 8. The In concentration is preferably equal to or less than one-twenty-fifth, and more preferably equal to or less than one-thirtieth that in the cathode 8.

In contrast, in the reference example shown in FIG. 5, the In concentration in the second light-emitting unit 72 exceeds one-twentieth that in the cathode 8.

According to this, it is understood that the entry of In is suppressed by the cathode buffer layer 41 in the first embodiment in which the cathode buffer layer 41 is provided. That is, as a result of suppressing the entry of In by the cathode buffer layer 41, the In concentration in the entire second light-emitting unit 72 including the second electron injection layer 20 is suppressed at a low level.

Moreover, it is understood that the entry of In is suppressed by the second electron injection layer 20 in the second embodiment in which the thick second electron injection layer 20 is provided. That is, as a result of suppressing the entry of In by the thick second electron injection layer 20, the In concentration in the layers of the second light-emitting unit 72 other than the second electron injection layer 20 is suppressed at a low level.

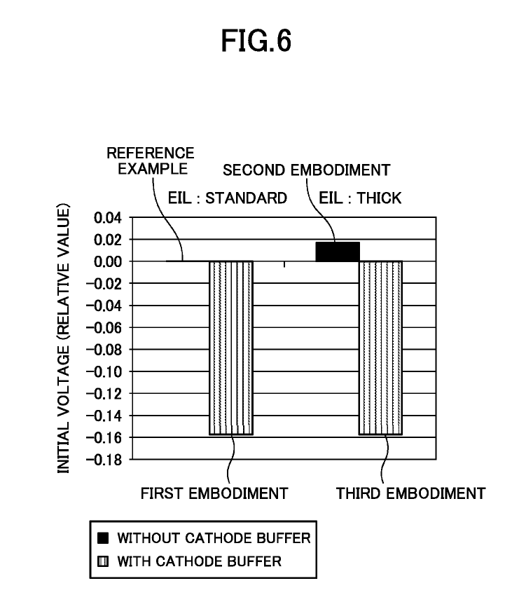

FIG. 6 is a graph representing an initial voltage required to cause a predetermined current to flow into the light-emitting unit by a relative value. In FIG. 6, the initial voltage in each of the first embodiment, the second embodiment, and a third embodiment is shown as a relative value with the initial voltage in the reference example being 0. The predetermined current is set to, for example, 15 mA/cm². The voltage is a voltage that is applied between the anode 6 and the cathode 8, which are disposed so as to interpose the organic film 7 including the light-emitting units 71 and 72 therebetween.

Here, the third embodiment is obtained by combining the first embodiment with the second embodiment. That is, the third embodiment includes both the cathode buffer layer 41 and the thick second electron injection layer 20. In the third embodiment, it is assumed that, for example, the thickness of the cathode 8 is 240 nm, the thickness of the cathode buffer layer 41 is 5 nm, the thickness of the second electron injection layer 20 is 60 nm, and the thickness of the second electron transport layer 19 is 20 nm.

According to this, in the first embodiment and the third embodiment in each of which the cathode buffer layer 41 is provided, the initial voltage is lowered compared to that in the reference example. It is considered that the resistivity was reduced because the cathode buffer layer 41 functioned as an electron supply source. Moreover, in the second embodiment in which the thick second electron injection layer 20 is provided, the initial voltage is slightly increased compared to that in the reference example. This is considered to be because the thickness of the second light-emitting unit 72 was increased.

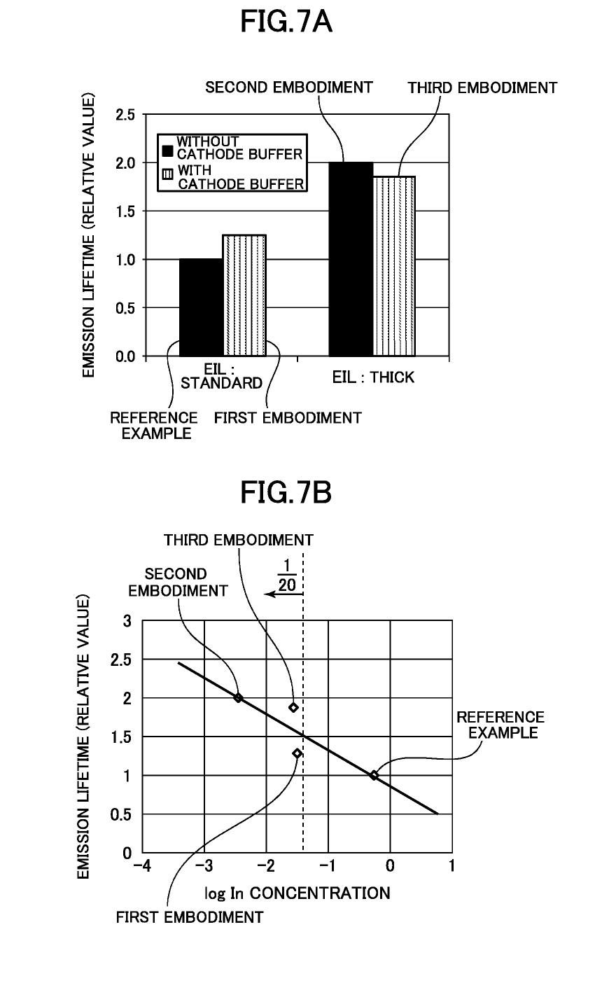

FIG. 7A is a graph representing the emission lifetime of the light-emitting unit by a relative value. In FIG. 7A, the emission lifetime in each of the first embodiment, the second embodiment, and the third embodiment is shown as a relative value with the emission lifetime in the reference example being 1. FIG. 7B is a graph representing the relationship between the In concentration and the emission lifetime. In FIG. 7B, the relationship between the In concentration in the second light-emitting layer 18 and the emission lifetime in each of the embodiments is plotted.

The emission lifetime is set to, for example, the time until the luminance deteriorates to 95%. Herein, the luminance of light emitted by the second light-emitting layer 18 included in the second light-emitting unit 72 is measured. The luminance of light emitted by the second light-emitting layer 18 is measured by, for example, extracting the component of an emission color (e.g., blue) of the second light-emitting layer 18 by spectroscopy.

According to this, in the first embodiment in which the cathode buffer layer 41 is provided, the emission lifetime is increased compared to that in the reference example. This is considered to be because the amount of In reaching the second light-emitting layer 18 was reduced by the cathode buffer layer 41. Moreover, also in the second embodiment in which the thick second electron injection layer 20 is provided, the emission lifetime is increased compared to that in the reference example. This is considered to be because the amount of In reaching the second light-emitting layer 18 was reduced by the thick second electron injection layer 20.

Moreover, the emission lifetime in the second embodiment is longer than that in the first embodiment. This is considered to be because the In concentration in the second embodiment is lower than that in the first embodiment (see FIGS. 3B and 4B).

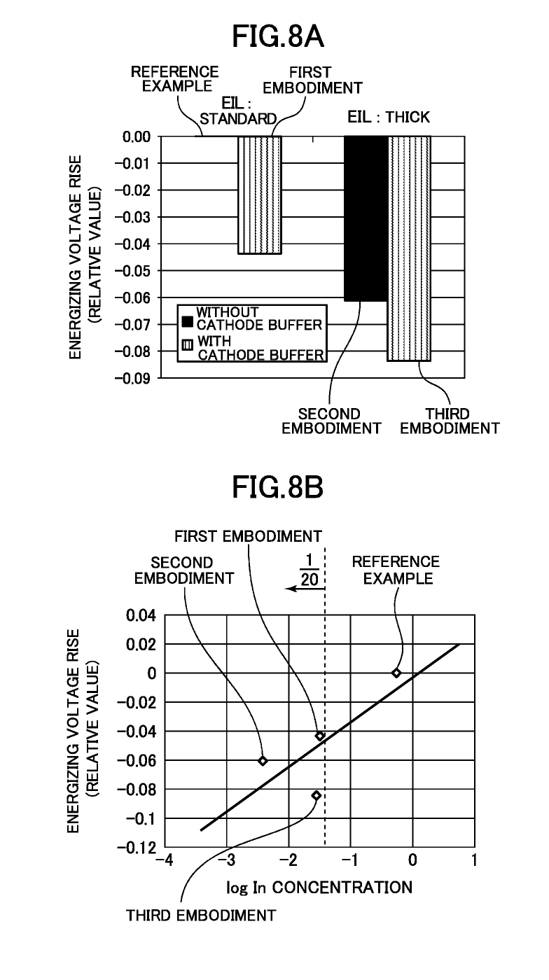

FIG. 8A is a graph representing an energizing voltage rise in the light-emitting unit by a relative value. In FIG. 8A, the energizing voltage rise in each of the first embodiment, the second embodiment, and the third embodiment is shown as a relative value with the energizing voltage rise in the reference example being 0. FIG. 8B is a graph representing the relationship between the In concentration and the energizing voltage rise.

The energizing voltage rise is a change in the voltage, which is required to cause a predetermined current to flow, from the initial voltage after a lapse of a predetermined time. The predetermined current is set to, for example, 15 mA/cm². The predetermined time is set to, for example, 100 hours.

According to this, in the first embodiment in which the cathode buffer layer 41 is provided, the energizing voltage rise is low compared to that in the reference example. This is considered to be because the amount of In entering the second light-emitting unit 72 was reduced by the cathode buffer layer 41. Moreover, also in the second embodiment in which the thick second electron injection layer 20 is provided, the energizing voltage rise is low compared to that in the reference example. This is considered to be because the resistivity is less likely to change even with the entry of In because the second electron injection layer 20 is thick.

According to the embodiments of the invention described above, the emission lifetime is improved, and the energizing voltage rise is suppressed. Therefore, it is possible to achieve reliability improvement and lower power consumption in the organic EL display device when the organic EL display device is formed into a panel.

While there have been described what are at present considered to be certain embodiments of the invention, it will be understood that various modifications may be made thereto, and it is intended that the appended claims cover all such modifications as fall within the true spirit and scope of the invention.

What is claimed is:

1. An organic EL display device comprising:
an anode;
an organic light-emitting unit formed on the anode; and
a cathode formed on the organic light-emitting unit and containing In, wherein
the organic light-emitting unit includes
a light-emitting layer, and
an electron injection layer formed between the cathode and the light-emitting layer, and
an In concentration in layers of the organic light-emitting unit other than the electron injection layer is equal to or less than one-twentieth that in the cathode.

2. The organic EL display device according to claim 1, wherein
an In concentration in the light-emitting layer is equal to or less than one-twentieth that in the cathode.

3. The organic EL display device according to claim 1, wherein
the organic light-emitting unit further includes an electron transport layer formed between the electron injection layer and the light-emitting layer, and
an In concentration in the electron transport layer is equal to or less than one-twentieth that in the cathode.

4. The organic EL display device according to claim 1, further comprising a cathode buffer layer formed between the cathode and the organic light-emitting unit and containing an alkali metal or an alkaline earth metal as a main component.

5. The organic EL display device according to claim 4, wherein
the cathode buffer layer contains Ca as a main component.

6. The organic EL display device according to claim 4, wherein
an In concentration in the electron injection layer is also equal to or less than one-twentieth that in the cathode.

7. The organic EL display device according to claim 3, wherein
the electron injection layer is doped with an alkali metal, and
the thickness of the electron injection layer is equal to or greater than two times that of the electron transport layer.

8. An organic EL display device comprising:
an anode;
an organic light-emitting unit formed on the anode;
a cathode formed on the organic light-emitting unit and containing In; and
a cathode buffer layer formed between the cathode and the organic light-emitting unit and containing an alkali metal or an alkaline earth metal as a main component.
